(19) United States
(12) Patent Application Publication
(10) Pub. No.: US 2025/0159798 A1
(43) Pub. Date: May 15, 2025

(54) PRINTED WIRING BOARD

(71) Applicants: SUMITOMO ELECTRIC PRINTED CIRCUITS, INC., Shiga (JP); SUMITOMO ELECTRIC INDUSTRIES, LTD., Osaka (JP)

(72) Inventors: Satoshi KIYA, Shiga (JP); Kazuo MURATA, Shiga (JP); Hiroshi UEDA, Osaka (JP); Suguru YAMAGISHI, Osaka (JP); Ichiro KUWAYAMA, Osaka (JP); Yuichi NAKAMURA, Osaka (JP); Takanori FUKUNAGA, Osaka (JP)

(73) Assignees: SUMITOMO ELECTRIC PRINTED CIRCUITS, INC., Shiga (JP); SUMITOMO ELECTRIC INDUSTRIES, LTD., Osaka (JP)

(21) Appl. No.: 18/839,087

(22) PCT Filed: Feb. 22, 2023
(86) PCT No.: PCT/JP2023/006433

§ 371 Date: Aug. 16, 2024

(30) Foreign Application Priority Data
Feb. 22, 2022 (JP) 2022-025560

(51) Int. Cl. H05K 1/02

(52) U.S. Cl. CPC H05K 1/0298

(57) ABSTRACT

The printed wiring board includes a base film, a first conductor pattern, a protective layer, a conductive adhesive layer, and a conductor film. The base film has a first main surface. The first conductor pattern is disposed on the first main surface. The first conductor pattern includes a signal pattern, a first ground pattern, and a second ground pattern, each of which extends along a first direction in a planar view. The signal pattern is disposed between the first ground pattern and the second ground pattern in a second direction orthogonal to the first direction. The protective layer is disposed on the first main surface so as to cover the first conductor pattern.

### TECHNICAL FIELD

The present disclosure relates to a printed wiring board. The present application claims the benefit of priority to Japanese Patent Application No. 2022-025560 filed on Feb. 22, 2022. The entire contents described in the Japanese patent applications are incorporated herein by reference.

### BACKGROUND ART

For example, Japanese Patent Laying-Open No. 2017-212472 (PTL 1) describes a shielded printed wiring board. The shielded printed wiring board described in PTL 1 includes a base film, a signal wiring pattern, a ground wiring pattern, an insulating film, a conductive adhesive layer, and a metal layer.

The signal wiring pattern and the ground wiring pattern are disposed on the base film. The insulating film is disposed on the base film so as to cover the signal wiring pattern and the ground wiring pattern. The insulating film is formed with an opening to expose the ground wiring pattern.

The conductive adhesive layer is disposed on the insulating film. The conductive adhesive layer is filled in the opening formed in the insulating film. Thus, the conductive adhesive layer is electrically connected to the ground wiring pattern. The metal layer is disposed on the conductive adhesive layer.

### CITATION LIST

### Patent Literature

PTL 1: Japanese Patent Laying-Open No. 2017-212472

### SUMMARY OF INVENTION

A printed wiring board according to an embodiment of the present disclosure includes a base film, a first conductor pattern, a protective layer, a conductive adhesive layer, and a conductor film. The base film has a first main surface. The first conductor pattern is disposed on the first main surface. The first conductor pattern includes a signal pattern, a first ground pattern, and a second ground pattern, each of which extends along a first direction in a planar view. The signal pattern is disposed between the first ground pattern and the second ground pattern in a second direction orthogonal to the first direction. The protective layer is disposed on the first main surface so as to cover the first conductor pattern. The protective layer is formed with a plurality of first openings which are configured to penetrate a portion of the protective layer on the first ground pattern along a thickness direction and are arranged in a row along the first direction, and a plurality of second openings which are configured to penetrate a portion of the protective layer on the second ground pattern along the thickness direction and are arranged in a row along the first direction. The conductive adhesive layer includes a portion disposed on the protective layer, a portion disposed inside each of the plurality of first openings, and a portion disposed inside each of the plurality of second openings. The conductor film is disposed on the conductive adhesive layer. A spacing between two adjacent openings of the plurality of first openings or a spacing between two adjacent openings of the plurality of second openings are equal to or smaller than one half of a wavelength of an electromagnetic wave having a frequency equal to that of a current flowing through the signal pattern.

### BRIEF DESCRIPTION OF DRAWINGS

FIG. 1 is a planar view of a printed wiring board 100;

FIG. 2 is a bottom view of the printed wiring board 100;

FIG. 3 is a cross-sectional view taken along line III-III in FIG. 1;

FIG. 4 is a process chart illustrating a method of manufacturing the printed wiring board 100;

FIG. 5 is a cross-sectional view illustrating a preparation step S1;

FIG. 6 is a cross-sectional view illustrating a patterning step S2;

FIG. 7 is a cross-sectional view illustrating an opening forming step S3;

FIG. 8 is a cross-sectional view illustrating a conductor layer forming step S4;

FIG. 9 is a cross-sectional view illustrating a protective layer attaching step S5;

FIG. 10 is a cross-sectional view of a first modification of the printed wiring board 100;

FIG. 11 is a planar view of a second modification of the printed wiring board 100;

FIG. 12 is a cross-sectional view of a third modification of the printed wiring board 100; and

FIG. 13 is a cross-sectional view of a fourth modification of the printed wiring board 100.

### DETAILED DESCRIPTION

### Problem to be Solved by the Present Disclosure

In the shielded printed wiring board described in PTL 1, it is not clear how the openings formed in the insulating film and filled with the conductive adhesive layer are arranged. Therefore, in the shielded wiring board described in PTL 1, the electromagnetic wave radiated from the signal wiring pattern may leak out from the lateral side through the insulating film.

The present disclosure has been made in view of the problems of the prior art mentioned above. More specifically, the present disclosure provides a printed wiring board capable of preventing an electromagnetic wave radiated from a signal pattern from leaking out from a lateral side through a protective layer.

### Advantageous Effect of the Present Disclosure

According to the printed wiring board of the present disclosure, it is possible to prevent the electromagnetic wave radiated from the signal pattern from leaking out from a lateral side through the protective layer.

### Description of Embodiments

First, embodiments of the present disclosure will be described.

(1) A printed wiring board according to an embodiment of the present disclosure includes a base film, a first conductor pattern, a protective layer, a conductive adhesive layer, and a conductor film. The base film has a first main surface. The first conductor pattern is disposed on the first main surface. The first conductor pattern includes a signal pattern, a first ground pattern, and a second ground pattern, each of which extends along a first direction in a planar view. The signal pattern is disposed between the first ground pattern and the second ground pattern in a second direction orthogonal to the first direction. The protective layer is disposed on the first main surface so as to cover the first conductor pattern. The protective layer is formed with a plurality of first openings which are configured to penetrate a portion of the protective layer on the first ground pattern along a thickness direction and are arranged in a row along the first direction, and a plurality of second openings which are configured to penetrate a portion of the protective layer on the second ground pattern along the thickness direction and are arranged in a row along the first direction. The conductive adhesive layer includes a portion disposed on the protective layer, a portion disposed inside each of the plurality of first openings, and a portion disposed inside each of the plurality of second openings. The conductor film is disposed on the conductive adhesive layer. A spacing between two adjacent openings of the plurality of first openings or a spacing between two adjacent openings of the plurality of second openings are equal to or smaller than one half of a wavelength of an electromagnetic wave having a frequency equal to that of a current flowing through the signal pattern.

According to the printed wiring board described in (1), it is possible to prevent the electromagnetic wave radiated from the signal pattern from leaking out from a lateral side through the protective layer.

(2) The printed wiring board described in (1) may further include a second conductor pattern, a plurality of first conductor layers, and a plurality of second conductor layers. The base film may have a second main surface opposite to the first main surface. The second conductor pattern may include a third ground pattern which is disposed on the second main surface and is configured to overlap with the signal pattern, the first ground pattern and the second ground pattern in a planar view. The base film may be formed with a plurality of third openings and a plurality of fourth openings which are configured to penetrate the base film in a thickness direction. The plurality of third openings may be configured to overlap with the first ground pattern in a planar view and may be arranged in a row along the first direction. The plurality of fourth openings may be configured to overlap with the second ground pattern in a planar view and may be arranged in a row along the first direction. Tach of the plurality of first conductor layers may be disposed inside each of the plurality of third openings. Each of the plurality of second conductor layers may be disposed inside each of the plurality of fourth openings. The spacing between two adjacent openings of the plurality of first openings and the spacing between two adjacent openings of the plurality of second openings may be equal to or smaller than a spacing between two adjacent openings of the plurality of third openings and a spacing between two adjacent openings of the plurality of fourth openings, respectively.

According to the printed wiring board described in (2), it is possible to further prevent the electromagnetic wave radiated from the signal pattern from leaking out from a lateral side through the protective layer.

### Details of Embodiments of the Present Disclosure

Hereinafter, the details of embodiments of the present disclosure will be described with reference to the drawings. In the following drawings, the same or corresponding parts are denoted by the same reference numerals, and the description thereof will not be repeated. The printed wiring board according to an embodiment is referred to as a printed wiring board 100.

### (Configuration of Printed Wiring Board 100)

The configuration of the printed wiring board 100 will be described below.

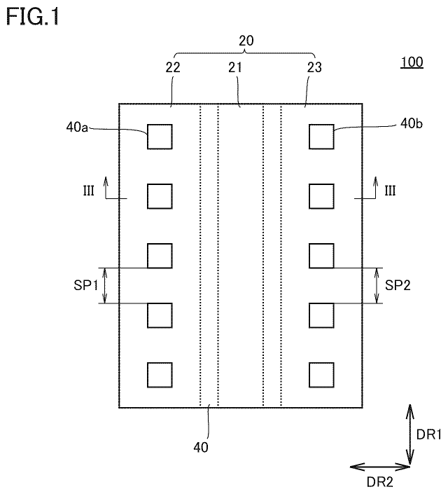

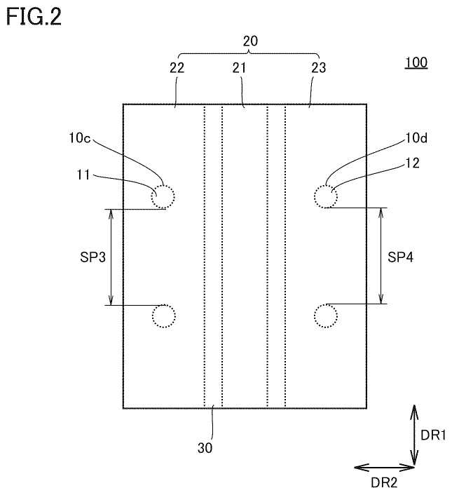

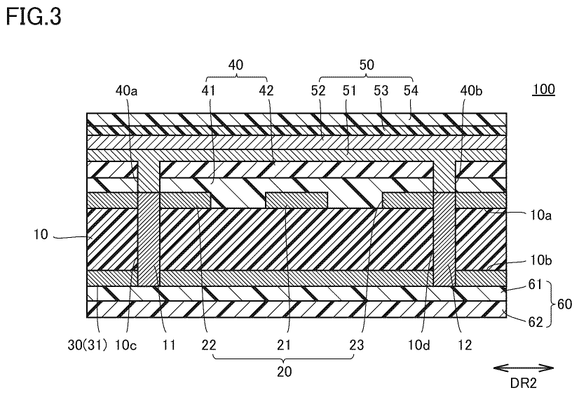

FIG. 1 is a planar view of the printed wiring board 100. In FIG. 1, a shield film 50 is not illustrated. FIG. 2 is a bottom view of the printed wiring board 100. In FIG. 2, a protective layer 60 is not illustrated. FIG. 3 is a cross-sectional view taken along line III-III in FIG. 1. As illustrated in FIGS. 1, 2 and 3, the printed wiring board 100 includes a base film 10, a first conductor pattern 20, a second conductor pattern 30, a protective layer 40, and a shield film 50.

The base film 10 is made of a flexible electrically insulating resin material. For example, the base film 10 is made of a fluororesin. The base film 10 has a first main surface 10a and a second main surface 10b. The first main surface 10a and the second main surface 10b are end surfaces in the thickness direction of the base film 10. The second main surface 10b is opposite to the first main surface 10a.

The first conductor pattern 20 is disposed on the first main surface 10a. The first conductor pattern 20 includes a signal pattern 21, a first ground pattern 22, and a second ground pattern 23. The first conductor pattern 20 is made of an electrically conductive material. For example, the first conductor pattern 20 is made of copper (Cu). A signal is applied to the signal pattern 21, and an AC current flows through the same. The first ground pattern 22 and the second ground pattern 23 have a ground potential.

The signal pattern 21, the first ground pattern 22, and the second ground pattern 23 extend along a first direction DR1 in a planar view. The signal pattern 21 is disposed between the first ground pattern 22 and the second ground pattern 23 in a second direction DR2. The second direction DR2 is orthogonal to the first direction DR1. The signal pattern 21 is separated from the first ground pattern 22 and the second ground pattern 23 in the second direction DR2. The width of the signal pattern 21 in the second direction DR2 is smaller than, for example, the width of the first ground pattern 22 in the second direction DR2 and the width of the second ground pattern 23 in the second direction DR2.

The second conductor pattern 30 is disposed on the second main surface 10b. The second conductor pattern 30 has a third ground pattern 31. The third ground pattern 31 is disposed so as to overlap with the signal pattern 21, the first ground pattern 22, and the second ground pattern 23 in a planar view. The second conductor pattern 30 is made of an electrically conductive material. For example, the second conductor pattern 30 is made of copper.

The protective layer 40 includes a first layer 41 and a second layer 42. The first layer 41 is disposed on the first main surface 10a so as to cover the first conductor pattern 20 (the signal pattern 21, the first ground pattern 22, and the second ground pattern 23). The first layer 41 is made of, for example, an epoxy adhesive. The second layer 42 is disposed on the first layer 41. The second layer 42 is made of, for example, polyimide.

The protective layer 40 is formed with a plurality of first openings 40a and a plurality of second openings 40b. The plurality of first openings 40a and the plurality of second openings 40b penetrate the protective layer 40 in the thickness direction. The plurality of first openings 40a are disposed so as to overlap with the first ground pattern 22 in a planar view, and the plurality of second openings 40b are disposed so as to overlap with the second ground pattern 23 in a planar view. In other words, the first ground pattern 22 and the second ground pattern 23 are exposed from the plurality of first openings 40a and the plurality of second openings 40b, respectively.

The plurality of first openings 40a are arranged in a row along the first direction DR1 in a planar view. The plurality of first openings 40a are separated from each other with an equal spacing, for example. A spacing between two adjacent first openings 40a is defined as a spacing SP1. The plurality of second openings 40b are arranged in a row along the first direction DR1 in a planar view. The plurality of second openings 40b are separated from each other with an equal spacing, for example. A spacing between two adjacent second openings 40b is defined as a spacing SP2.

The spacing SP1 and the spacing SP2 are equal to or smaller than one half of a wavelength of an electromagnetic wave radiated from the signal pattern 21. The frequency of the electromagnetic wave radiated from the signal pattern 21 is equal to the frequency of a current flowing through the signal pattern 21.

The first opening 40a and the second opening 40b have, for example, a rectangular shape in a planar view. The first opening 40a and the second opening 40b may have a square shape in a planar view. The opening area of each of the first openings 40a in a planar view or the opening area of each of the second openings 40b in a planar view is preferably 0.09 mm² or more.

The base film 10 is formed with a plurality of third openings 10c and a plurality of fourth openings 10d. The plurality of third openings 10c and the plurality of fourth openings 10d penetrate the base film 10 in the thickness direction. The plurality of third openings 10c are disposed so as to overlap with the first ground pattern 22 in a planar view, and the plurality of fourth openings 10d are disposed so as to overlap with the second ground pattern 23 in a planar view. In other words, the first ground pattern 22 and the second ground pattern 23 are exposed from the plurality of third openings 10c and the plurality of fourth openings 10d, respectively.

The plurality of third openings 10c are arranged in a row along the first direction DR1 in a planar view. The plurality of third openings 10c are separated from each other with an equal spacing, for example. A spacing between two adjacent third openings 10c is defined as a spacing SP3. The plurality of fourth openings 10d are arranged in a row along the first direction DR1 in a planar view. The plurality of fourth openings 10d are separated from each other with an equal spacing, for example. A spacing between two adjacent fourth openings 10d is defined as a spacing SP4. Preferably, the spacing SP1 and the spacing SP2 are equal to or smaller than the spacing SP3 and the spacing SP4, respectively.

The first conductor layer 11 and the second conductor layer 12 are embedded in the third opening 10c and the fourth opening 10d, respectively. The first conductor layer 11 and the second conductor layer 12 are made of an electrically conductive material. For example, the first conductor layer 11 and the second conductor layer 12 are made of copper. The first conductor layer 11 electrically connects the first ground pattern 22 and the third ground pattern 31. The second conductor layer 12 electrically connects the second ground pattern 23 and the third ground pattern 31.

The shield film 50 includes a conductive adhesive layer 51 and a conductor film 52. The conductive adhesive layer 51 has a portion disposed on the protective layer 40 (the second layer 42), a portion embedded in the first opening 40a, and a portion embedded in the second opening 40b. Thus, the conductive adhesive layer 51 is electrically connected to the first ground pattern 22 and the second ground pattern 23.

The third opening 10c and the fourth opening 10d have, for example, a circular shape in a planar view. The opening area of each of the third openings 10c in the planar view or the opening area of each of the fourth openings 10d in the planar view is smaller than the opening area of each of the first openings 40a in the planar view or the opening area of each of the second openings 40b in the planar view, for example.

The conductive adhesive layer 51 is made of a conductive adhesive. More specifically, the conductive adhesive layer 51 is made of a conductive adhesive that contains a conductive filler. The conductive filler is made of, for example, silver (Ag). The conductive adhesive layer 51 may be made of an isotropic conductive adhesive or an anisotropic conductive adhesive. The conductor film 52 is disposed on the conductive adhesive layer 51. The conductor film 52 is made of an electrically conductive material. For example, the conductor film 52 is made of copper.

The conductivity of the conductive adhesive layer 51 is smaller than the conductivity of the conductor film 52. For example, the conductivity of the conductive adhesive layer 51 is 1.0×10¹ S/m or more. The conductivity of the conductive adhesive layer 51 is preferably 3.2×10¹ S/m or more, and more preferably 1.2×10² S/m or more. For example, the conductivity of the conductor film 52 is 1.0×10⁷ S/m or more. The conductivity of the conductor film 52 is preferably 2.0×10⁷ S/m or more, and more preferably 3.0×10⁷ S/m or more.

The conductivity of the conductive adhesive layer 51 is determined by the following method. Firstly, a connection resistance between the conductor film 52 and the first ground pattern 22 (the second ground pattern 23) is measured. Secondly, a value is calculated by dividing the product of the measured connection resistance between the conductor film 52 and the first ground pattern 22 (the second ground pattern 23) and the opening area of the first opening 40a (the opening area of the second opening 40b) by the thickness of the conductive adhesive layer 51. This value is defined as the conductivity of the conductive adhesive layer 51.

The printed wiring board 100 may further include a protective layer 60. The protective layer 60 includes a first layer 61 and a second layer 62. The first layer 61 is made of, for example, an epoxy adhesive. The second layer 62 is disposed on the first layer 61. The second layer 62 is made of, for example, polyimide. The shield film 50 may include an insulating layer 53 and an insulating layer 54. The insulating layer 53 is disposed on the conductor film 52. The insulating layer 53 is made of, for example, an epoxy resin, an acrylic resin, or the like. However, the constituent material of the insulating layer 53 is not limited thereto. The insulating layer 54 is disposed on the insulating layer 53. The insulating layer 54 is made of, for example, a polyimide, a liquid crystal polymer, a PEEK (polyether ether ketone) resin, an epoxy resin, an acrylic resin, or the like. However, the constituent material of the insulating layer 54 is not limited thereto.

### (Method of Manufacturing Printed Wiring Board 100)

Hereinafter, a method of manufacturing a printed wiring board 100 will be described.

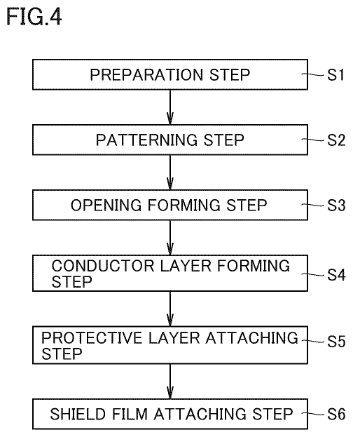

FIG. 4 is a process chart illustrating a method of manufacturing a printed wiring board 100. As illustrated in FIG. 4, the method of manufacturing a printed wiring board 100 includes a preparation step S1, a patterning step S2, an opening forming step S3, a conductor layer forming step S4, a protective layer attaching step S5, and a shield film attaching step S6.

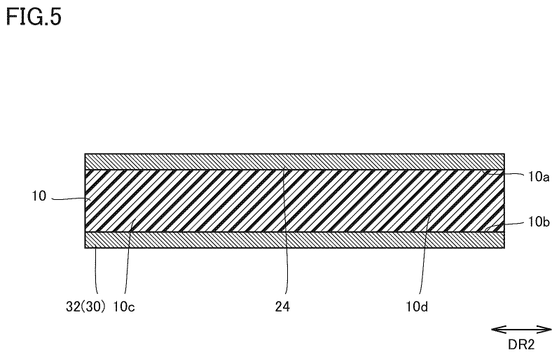

FIG. 5 is a cross-sectional view illustrating the preparation step S1. As illustrated in FIG. 5, in the preparation step S1, a base film 10 is prepared. In the base film 10 prepared in the preparation step S1, a copper foil 24 is disposed on the first main surface 10a, and a copper foil 32 is disposed on the second main surface 10b. The copper foil 32 serves as the second conductor pattern 30 (the third ground pattern 31).

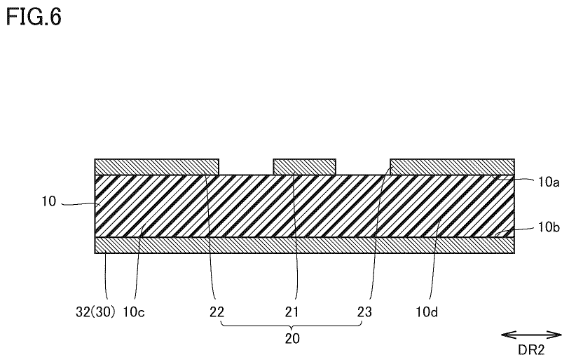

FIG. 6 is a cross-sectional view illustrating the patterning step S2. As illustrated in FIG. 6, in the patterning step S2, the copper foil 24 is patterned to form a signal pattern 21, a first ground pattern 22, and a second ground pattern 23. In the patterning step of the copper foil 24, firstly, a dry film resist, for example, is attached to the copper foil 24. Secondly, the attached dry film resist is developed and exposed. Thirdly, the developed and exposed dry film resist is used as a mask to etch the copper foil 24, thereby forming the signal pattern 21, the first ground pattern 22, and the second ground pattern 23.

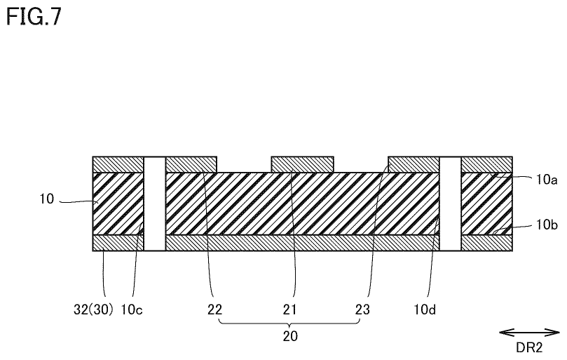

FIG. 7 is a cross-sectional view illustrating the opening forming step S3. As illustrated in FIG. 7, in the opening forming step S3, a third opening 10c and a fourth opening 10d are formed. The third opening 10c and the fourth opening 10d are formed by, for example, laser irradiation.

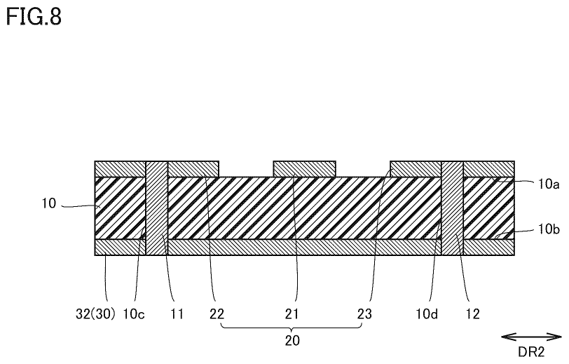

FIG. 8 is a cross-sectional view illustrating the conductor layer forming step S4. As illustrated in FIG. 8, in the conductor layer forming step S4, a first conductor layer 11 and a second conductor layer 12 are formed. The first conductor layer 11 and the second conductor layer 12 are formed by, for example, an electroless plating method or an electrolytic plating method.

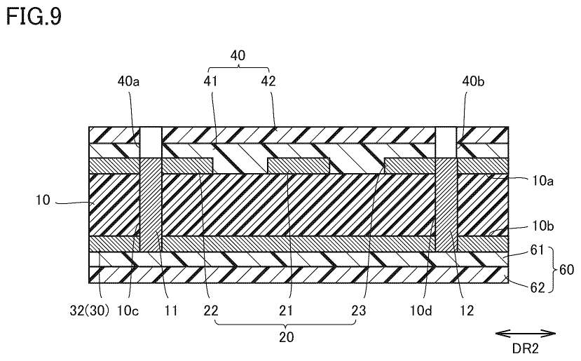

FIG. 9 is a cross-sectional view illustrating the protective layer attaching step S5. As illustrated in FIG. 9, in the protective layer attaching step S5, a protective layer 40 is attached to the first main surface 10a. In the protective layer attaching step S5, firstly, the protective layer 40 is disposed on the first main surface 10a. At this time, the first layer 41 is uncured. The protective layer 40 is formed in advance with a first opening 40a and a second opening 40b. Secondly, the first layer 41 is cured by heating. Thus, the protective layer 40 is attached to the first main surface 10a. In the protective layer attaching step S5, the protective layer 60 is also attached to the second conductor pattern 30 (the copper foil 32) in the same manner as the protective layer 40.

In the shield film attaching step S6, a shield film 50 is attached to the protective layer 40. In the shield film attaching step S6, firstly, the shield film 50 is disposed on the protective layer 40. At this time, the conductive adhesive layer 51 is uncured. While the shield film 50 is being disposed on the protective layer 40, the uncured conductive adhesive layer 51 is also filled in the first opening 40a and the second opening 40b. Secondly, the uncured conductive adhesive layer 51 is cured by heating, whereby the shield film 50 is attached to the protective layer 40. Thus, the printed wiring board 100 having the configuration illustrated in FIGS. 1 to 3 is formed.

### (Effects of Printed Circuit Board 100)

The effects of the printed wiring board 100 will be described below.

In the printed wiring board 100, the spacing between the conductive adhesive layers 51 embedded in the two adjacent first openings 40a or the spacing between the conductive adhesive layers 51 embedded in the two adjacent second openings 40b is smaller. More specifically, the spacing SP1 or the spacing SP2 is equal to or smaller than one half of the wavelength of the electromagnetic wave having the same frequency as that of the current flowing through the signal pattern 21.

Therefore, in the printed wiring board 100, it is difficult for the electromagnetic wave radiated from the signal pattern 21 to pass through the spacing between the conductive adhesive layers 51 embedded in two adjacent first openings 40a or the spacing between the conductive adhesive layers 51 embedded in two adjacent second openings 40b. As described above, according to the printed wiring board 100, it is possible to prevent the electromagnetic wave radiated from the signal pattern 21 from leaking out from the lateral side through the protective layer 40.

If the spacing SP1 and the spacing SP2 are equal to or smaller than the spacing SP3 and the spacing SP4, respectively, it is further difficult for the electromagnetic wave radiated from the signal pattern 21 to pass through the spacing between the conductive adhesive layers 51 embedded in two adjacent first openings 40a or the spacing between the conductive adhesive layers 51 embedded in two adjacent second openings 40b, which makes it possible to further prevent the electromagnetic wave radiated from the signal pattern 21 from leaking out from the lateral side through the protective layer 40.

If the opening area of the first opening 40a in the planar view or the opening area of the second opening 40b in the planar view is 0.09 mm² or more, it is possible to further prevent the electromagnetic wave radiated from the signal pattern 21 from leaking out from the lateral side through the protective layer 40.

### (Simulation)

Hereinafter, a simulation was performed to confirm the effects of the printed wiring board 100. Sample 1 and sample 2 were provided for the simulation. The sample 1 corresponds to the printed wiring board 100. Sample 2 has the same configuration as sample 1 except that the first opening 40a and the second opening 40b are filled with copper instead of the conductive adhesive layer 51.

In the simulation, the realized gain of an electromagnetic wave radiated from the signal pattern 21 and passing through the protective layer 40 was calculated by modifying the spacing SP1, the spacing SP2 and the frequency of the current flowing through the signal pattern 21. The spacing SP1 and the spacing SP2 were set in a range of 0.1 mm to 35 mm.

In sample 1, the first opening 40a or the second opening 40b was formed to have a rectangular shape in the planar view, and more specifically, the first opening 40a or the second opening 40b was formed to have a square shape with a side length of 0.4 mm in the planar view. In sample 2, the first opening 40a or the second opening 40b was formed to have a circular shape with an inner diameter of 0.15 mm in the planar view.

Table 1 and Table 2 show simulation results regarding the realized gain of each electromagnetic wave passing through the protective layer 40 for sample 1. Table 3 and Table 4 show simulation results regarding the realized gain of each electromagnetic wave passing through the protective layer 40 for sample 2.

TABLE 1

| Frequency of | | | | | | | | | | | | | | | | | | | | | | |
|---|---|---|---|---|---|---|---|---|---|---|---|---|---|---|---|---|---|---|---|---|---|---|
| electromagnetic | | | | | | | | | | | | | | | | | | | | | | |
| wave radiated | | | | | | | | | | | | | | | | | | | | | | |
| from signal | Spacing SP1 and Spacing SP2 (mm) | | | | | | | | | | | | | | | | | | | | | |
| pattern 21 (GHz) | 0.10 | | 0.25 | | 0.30 | | 0.40 | | 0.50 | | 0.70 | | 0.75 | | 1.00 | | 1.25 | | 1.75 | | 2.50 | |
| 1 | −145 | dB | −157 | dB | −158 | dB | −158 | dB | −156 | dB | −149 | dB | −141 | dB | −154 | dB | −142 | dB | −134 | dB | −129 | dB |
| 5 | −118 | dB | −129 | dB | −136 | dB | −132 | dB | −130 | dB | −127 | dB | −126 | dB | −127 | dB | −120 | dB | −115 | dB | −109 | dB |
| 10 | −97 | dB | −115 | dB | −113 | dB | −115 | dB | −114 | dB | −114 | dB | −113 | dB | −110 | dB | −106 | dB | −96 | dB | −88 | dB |
| 20 | −71 | dB | −97 | dB | −97 | dB | −99 | dB | −98 | dB | −95 | dB | −90 | dB | −91 | dB | −87 | dB | −82 | dB | −61 | dB |
| 30 | −64 | dB | −86 | dB | −86 | dB | −86 | dB | −85 | dB | −78 | dB | −77 | dB | −66 | dB | −59 | dB | −49 | dB | −36 | dB |

TABLE 2

| Frequency of | | | | | | | | | | | | | | | | | | | |
|---|---|---|---|---|---|---|---|---|---|---|---|---|---|---|---|---|---|---|---|
| electromagnetic | | | | | | | | | | | | | | | | | | | |
| wave radiated | | | | | | | | | | | | | | | | | | | |
| from signal | Spacing SP1 and Spacing SP2 (mm) | | | | | | | | | | | | | | | | | | |
| pattern 21 (GHz) | 3.75 | | 5.00 | | 6.25 | | 7.50 | | 8.75 | | 10.0 | | 12.5 | | 15.0 | 17.5 | 20.0 | 25.0 | 35.0 |
| 1 | −122 | dB | −112 | dB | −117 | dB | −110 | dB | −105 | dB | −101 | dB | −104 | dB | −97 dB | −98 dB | −91 dB | −94 dB | −85 dB |
| 5 | −100 | dB | −92 | dB | −89 | dB | −82 | dB | −80 | dB | −78 | dB | −62 | dB | −67 dB | −61 dB | −58 dB | −59 dB | −59 dB |
| 10 | −82 | dB | −78 | dB | −71 | dB | −60 | dB | −46 | dB | −44 | dB | −49 | dB | −52 dB | −51 dB | −47 dB | −53 dB | −54 dB |
| 20 | −40 | dB | −31 | dB | −39 | dB | −46 | dB | −39 | dB | −36 | dB | −42 | dB | −37 dB | −41 dB | −38 dB | −41 dB | −43 dB |
| 30 | −34 | dB | −39 | dB | −28 | dB | −38 | dB | −31 | dB | −31 | dB | −28 | dB | −31 dB | −36 dB | −39 dB | −33 dB | −36 dB |

TABLE 3

| Frequency of | | | | | | | | | | | | | | | | | | | | | | |
|---|---|---|---|---|---|---|---|---|---|---|---|---|---|---|---|---|---|---|---|---|---|---|
| electromagnetic | | | | | | | | | | | | | | | | | | | | | | |
| wave radiated | | | | | | | | | | | | | | | | | | | | | | |
| from signal | Spacing SP1 and Spacing SP2 (mm) | | | | | | | | | | | | | | | | | | | | | |
| pattern 21 (GHz) | 0.10 | | 0.25 | | 0.30 | | 0.40 | | 0.50 | | 0.70 | | 0.75 | | 1.00 | | 1.25 | | 1.75 | | 2.50 | |
| 1 | −164 | dB | −157 | dB | −159 | dB | −153 | dB | −150 | dB | −145 | dB | −145 | dB | −137 | dB | −135 | dB | −133 | dB | −121 | dB |
| 5 | −128 | dB | −131 | dB | −131 | dB | −129 | dB | −124 | dB | −118 | dB | −120 | dB | −118 | dB | −112 | dB | −105 | dB | −103 | dB |
| 10 | −116 | dB | −112 | dB | −115 | dB | −116 | dB | −110 | dB | −106 | dB | −105 | dB | −102 | dB | −96 | dB | −94 | dB | −85 | dB |
| 20 | −99 | dB | −99 | dB | −98 | dB | −98 | dB | −95 | dB | −88 | dB | −86 | dB | −84 | dB | −79 | dB | −76 | dB | −64 | dB |
| 30 | −89 | dB | −89 | dB | −88 | dB | −87 | dB | −86 | dB | −78 | dB | −76 | dB | −71 | dB | −67 | dB | −60 | dB | −50 | dB |

TABLE 4

| Frequency of | | | | | | | | | | | | | | | | | | | |
|---|---|---|---|---|---|---|---|---|---|---|---|---|---|---|---|---|---|---|---|
| electromagnetic | | | | | | | | | | | | | | | | | | | |
| wave radiated | | | | | | | | | | | | | | | | | | | |
| from signal | Spacing SP1 and Spacing SP2 (mm) | | | | | | | | | | | | | | | | | | |
| pattern 21 (GHz) | 3.75 | | 5.00 | | 6.25 | | 7.50 | | 8.75 | | 10.0 | | 12.5 | | 15.0 | 17.5 | 20.0 | 25.0 | 35.0 |
| 1 | −119 | dB | −112 | dB | −115 | dB | −112 | dB | −103 | dB | −107 | dB | −103 | dB | −99 dB | −96 dB | −96 dB | −91 dB | −86 dB |
| 5 | −99 | dB | −92 | dB | −88 | dB | −84 | dB | −80 | dB | −78 | dB | −67 | dB | −63 dB | −62 dB | −59 dB | −60 dB | −60 dB |
| 10 | −77 | dB | −74 | dB | −71 | dB | −62 | dB | −55 | dB | −56 | dB | −52 | dB | −50 dB | −49 dB | −49 dB | −50 dB | −51 dB |
| 20 | −57 | dB | −46 | dB | −42 | dB | −38 | dB | −39 | dB | −37 | dB | −39 | dB | −38 dB | −39 dB | −38 dB | −39 dB | −41 dB |
| 30 | −42 | dB | −33 | dB | −32 | dB | −32 | dB | −35 | dB | −32 | dB | −35 | dB | −36 dB | −33 dB | −32 dB | −33 dB | −36 dB |

In the simulation, a condition where the realized gain of the electromagnetic wave passing through the protective layer 40 (the base film 10) is less than −60 dB is defined as condition A. Further, a condition where the spacing SP1 or the spacing SP2 is equal to or smaller than one half of the wavelength of the electromagnetic wave having the same frequency as that of the current flowing through the signal pattern 21 is defined as condition B. The smaller the realized gain is, the more the electromagnetic wave is attenuated.

When the current flowing through the signal pattern 21 was 1 GHz, condition A was satisfied in sample 1 and sample 2 regardless of the spacing SP1 and the spacing SP2. In this case, as shown in Tables 1 to 4, condition B was also satisfied in sample 1 and sample 2 regardless of the spacing SP1 and the spacing SP2. Further, in this case, when the spacing SP1 and the spacing SP2 were equal to each other, the realized gain of the electromagnetic wave passing through the protective layer 40 was substantially the same in sample 1 and sample 2.

If the current flowing through the signal pattern 21 was 5 GHz, condition A was satisfied in sample 1 and sample 2 when the spacing SP1 and the spacing SP2 were within the range of 17.5 mm or less. In this case, if condition A was satisfied in sample 1 and sample 2, condition B was also satisfied. Further, in this case, when the spacing SP1 and the spacing SP2 were equal to each other, the realized gain of the electromagnetic wave passing through the protective layer 40 was substantially the same in sample 1 and sample 2.

If the current flowing through the signal pattern 21 was 10 GHz, condition A was satisfied in sample 1 and sample 2 when the spacing SP1 and the spacing SP2 were within the range of 7.50 mm or less. In this case, if condition A was satisfied in sample 1 and sample 2, condition B was also satisfied. Further, in this case, when the spacing SP1 and the spacing SP2 were equal to each other, the realized gain of the electromagnetic wave passing through the protective layer 40 was substantially the same in sample 1 and sample 2.

If the current flowing through the signal pattern 21 was 20 GHz, condition A was satisfied in sample 1 and sample 2 when the spacing SP1 and the spacing SP2 were within the range of 2.50 mm or less. In this case, if condition A was satisfied in sample 1 and sample 2, condition B was also satisfied. Further, in this case, when the spacing SP1 and the spacing SP2 were equal to each other, the realized gain of the electromagnetic wave passing through the protective layer 40 was substantially the same in sample 1 and sample 2.

If the current flowing through the signal pattern 21 was 30 GHz, condition A was satisfied in sample 1 and sample 2 when the spacing SP1 and the spacing SP2 were within the range of 1.25 mm or less. In this case, if condition A was satisfied in sample 1 and sample 2, condition B was also satisfied. Further, in this case, when the spacing SP1 and the spacing SP2 were equal to each other, the realized gain of the electromagnetic wave passing through the protective layer 40 was substantially the same in sample 1 and sample 2.

From the above comparison, it was obvious that it is possible to ensure the electromagnetic wave shielding effect achieved by the conductive adhesive layer 51 embedded in the first opening 40a and the second opening 40b by setting the spacing SP1 and the spacing SP2 equal to or smaller than one half of the wavelength of the electromagnetic wave having a frequency equal to that of the current flowing through the signal pattern 21, whereby it is less likely for the electromagnetic wave radiated from the signal pattern 21 to leak out from the lateral side of the printed wiring board 100 through the protective layer 40.

### (First Modification)

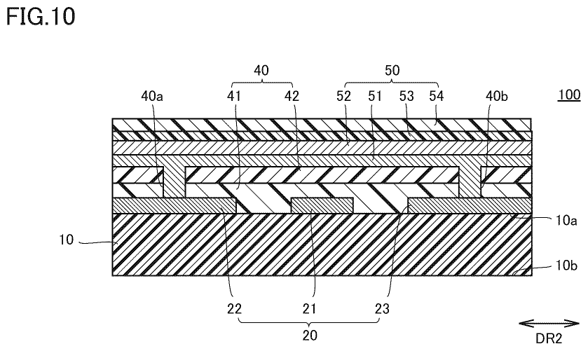

FIG. 10 is a cross-sectional view of a first modification of the printed wiring board 100. As illustrated in FIG. 10, the printed wiring board 100 may not include the second conductor pattern 30 and the protective layer 60.

### (Second Modification)

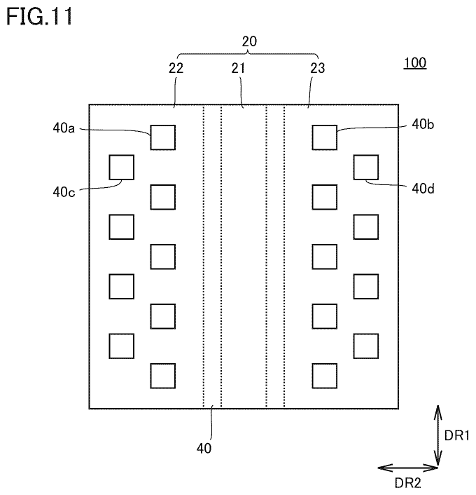

FIG. 11 is a planar view of a second modification of the printed wiring board 100. In FIG. 11, the shield film 50 is not illustrated. As illustrated in FIG. 11, the protective layer 40 may be further formed with a plurality of fifth openings 40c and a plurality of sixth openings 40d. The plurality of fifth openings 40c and the plurality of sixth openings 40d penetrate the protective layer 40 in the thickness direction. The plurality of fifth openings 40c are disposed so as to overlap with the first ground pattern 22 in a planar view, and the plurality of sixth opening 40d are disposed so as to overlap with the second ground pattern 23 in a planar view. In other words, the first ground pattern 22 and the second ground pattern 23 are exposed from the plurality of fifth openings 40c and the plurality of sixth openings 40d, respectively.

The plurality of fifth openings 40c are arranged in a row along the first direction DR1 in a planar view. The plurality of sixth openings 40d are arranged in a row along the first direction DR1 in a planar view. Each fifth opening 40c is disposed between two first openings 40a adjacent to each other in the first direction DR1, and each sixth opening 40d is disposed between two second openings 40b adjacent to each other in the first direction DR1. Although not illustrated, the conductive adhesive layer 51 is also embedded in the plurality of fifth openings 40c and the plurality of sixth openings 40d.

Even if the electromagnetic wave radiated from the signal pattern 21 passes between two adjacent first openings 40a (or two adjacent second openings 40b), the electromagnetic wave is shielded by the conductive adhesive layer 51 embedded in the plurality of fifth opening 40c (or the plurality of sixth opening 40d). Therefore, it is still less likely for the electromagnetic wave radiated from the signal pattern 21 to leak out from the lateral side of the printed wiring board 100 through the protective layer 40.

### (Third Modification)

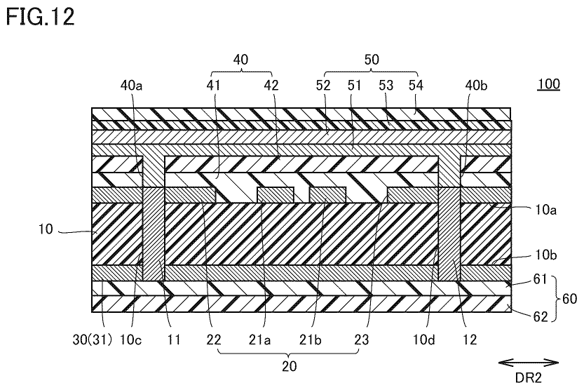

FIG. 12 is a cross-sectional view of a third modification of the printed wiring board 100. As illustrated in FIG. 12, the first conductor pattern 20 may include a signal pattern 21a and a signal pattern 21b instead of the signal pattern 21. The signal pattern 21a and the signal pattern 21b are separated from each other in the second direction DR2. For example, the signal pattern 21a is applied with a signal having a phase opposite to that of the signal pattern 21b. In other words, the signal pattern 21a and the signal pattern 21b are differential signal lines.

### (Fourth Modification)

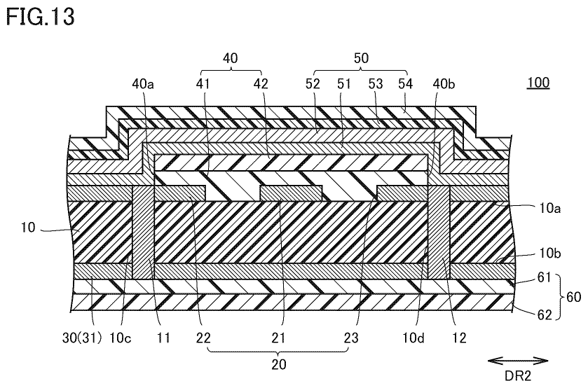

FIG. 13 is a cross-sectional view of a fourth modification of the printed wiring board 100. As described above, the shield film 50 is attached by thermocompression bonding. During this process, the shield film 50 may deform following the shape of the first opening 40a and the second opening 40b. Therefore, as illustrated in FIG. 13, a step may be formed on the upper surface of the printed wiring board 100 at a position where the first opening 40a is formed and at a position where the second opening 40b is formed.

It should be understood that the embodiments disclosed herein are illustrative and non-restrictive in every respect. The scope of the present invention is defined by the scope of the claims, rather than the embodiments described above, and is intended to include any modifications within the scope and meaning equivalent to the scope of the claims.

### REFERENCE SIGNS LIST

10: base film; 10a: first main surface; 10b: second main surface; 10c: third opening; 10d: fourth opening; 11: first conductor layer; 12: second conductor layer; 20: first conductor pattern; 21: conductor pattern; 21a, 21b: signal pattern; 22: first ground pattern; 23: second ground pattern; 24: copper foil; 30: second conductor pattern; 31: third ground pattern; 32: copper foil; 40: protective layer; 40a: first opening; 40b: second opening; 40c: fifth opening; 40d: sixth opening; 41: first layer; 42: second layer; 50: shield film; 51: conductive adhesive layer; 52: conductor film; 53: insulating layer; 54: insulating layer; 60: protective layer; 61: first layer; 62: second layer; 100: printed wiring board; DR1: first direction; DR2: second direction; S1: preparation step; S2: patterning step; S3: opening forming step; S4: conductor layer forming step; S5: protective layer attaching step; S6: shield film attaching step; SP1, SP2, SP3, SP4: spacing.

1. A printed wiring board comprising:
a base film;
a first conductor pattern;
a protective layer;
a conductive adhesive layer; and
a conductor film,
wherein the base film has a first main surface,
the first conductor pattern is disposed on the first main surface,
the first conductor pattern includes a signal pattern, a first ground pattern, and a second ground pattern, each of which extends along a first direction in a planar view,
the signal pattern is disposed between the first ground pattern and the second ground pattern in a second direction orthogonal to the first direction,
the protective layer is disposed on the first main surface so as to cover the first conductor pattern,
the protective layer is formed with a plurality of first openings which are configured to penetrate a portion of the protective layer on the first ground pattern along a thickness direction and are arranged in a row along the first direction, and a plurality of second openings which are configured to penetrate a portion of the protective layer on the second ground pattern along the thickness direction and are arranged in a row along the first direction,
the conductive adhesive layer includes a portion disposed on the protective layer, a portion disposed inside each of the plurality of first openings, and a portion disposed inside each of the plurality of second openings,
the conductor film is disposed on the conductive adhesive layer, and
a spacing between two adjacent openings of the plurality of first openings or a spacing between two adjacent openings of the plurality of second openings is equal to or smaller than one half of a wavelength of an electromagnetic wave having a frequency equal to that of a current flowing through the signal pattern.

2. The printed wiring board according to claim 1, further comprising:
a second conductor pattern;
a plurality of first conductor layers; and
a plurality of second conductor layers,
wherein the base film has a second main surface opposite to the first main surface,
the second conductor pattern includes a third ground pattern which is disposed on the second main surface and is configured to overlap with the signal pattern, the first ground pattern and the second ground pattern in a planar view,
the base film is formed with a plurality of third openings and a plurality of fourth openings which are configured to penetrate the base film in a thickness direction,
the plurality of third openings are configured to overlap with the first ground pattern in a planar view and are arranged in a row along the first direction,
the plurality of fourth openings are configured to overlap with the second ground pattern in a planar view and are arranged in a row along the first direction,
each of the plurality of first conductor layers is disposed inside each of the plurality of third openings,
each of the plurality of second conductor layers is disposed inside each of the plurality of fourth openings, and
the spacing between two adjacent openings of the plurality of first openings and the spacing between two adjacent openings of the plurality of second openings is equal to or smaller than a spacing between two adjacent openings of the plurality of third openings and a spacing between two adjacent openings of the plurality of fourth openings, respectively.
